(19) United States
(12) Patent Application Publication
(10) Pub. No.: US 2023/0336129 A1
(43) Pub. Date: Oct. 19, 2023

(54) AMPLIFIER CIRCUIT

(71) Applicant: Murata Manufacturing Co., Ltd., Kyoto (JP)

(72) Inventor: Makoto TABEI, Kyoto (JP)

(21) Appl. No.: 18/337,532

(22) Filed: Jun. 20, 2023

Related U.S. Application Data
(63) Continuation of application No. PCT/JP2021/043218, filed on Nov. 25, 2021.

(30) Foreign Application Priority Data
Dec. 23, 2020 (JP) 2020-213372

(51) Int. Cl. H03F 1/52

(52) U.S. Cl. CPC H03F 1/523; H03F 3/193

(57) ABSTRACT

An amplifier circuit includes an input terminal, an output terminal, a transistor provided in between the input terminal and the output terminal, and a coiled or meandered inductor. The transistor has a gate, a source, and a drain, and of these gate, source, and drain, two terminals are connected to ground terminals that are different from each other. The inductor is connected between the ground terminals to which the foregoing two terminals are connected.

### CROSS REFERENCE TO RELATED APPLICATION

This is a continuation of International Application No. PCT/JP2021/043218 filed on Nov. 25, 2021 which claims priority from Japanese Patent Application No. 2020-213372 filed on Dec. 23, 2020. The contents of these applications are incorporated herein by reference in their entireties.

### BACKGROUND ART

### Technical Field

The present disclosure relates to amplifier circuits.

A related art amplifier circuit is disclosed (for example, Patent Document 1). In this amplifier circuit, two terminals of a transistor provided in between an input terminal and an output terminal are connected to different ground terminals (terminals to be connected to ground), and an ESD (Electro Static Discharge) protection element is connected between these ground terminals. Because of this, the amplifier circuit can be protected from ESD.
Patent Document 1: U.S. patent Ser. No. 10/033,332 Specification

### BRIEF SUMMARY

However, with the amplifier circuit disclosed in the foregoing Patent Document 1, there is a case where a capacitance component of the ESD protection element functions dominantly. In such a case, a signal having the frequency that needs to be prevented from passing between the foregoing ground terminals may pass between the foregoing ground terminals via the ESD protection element and may cause an oscillation.

The present disclosure provides an amplifier circuit that facilitates both the ESD protection and the oscillation suppression.

An amplifier circuit according to one aspect of the present disclosure includes an input terminal, an output terminal, a first transistor provided in between the input terminal and the output terminal, and a coiled or meandered inductor. The first transistor has a first control terminal, a first terminal, and a second terminal, of the first control terminal, the first terminal, and the second terminal, two terminals are connected to ground terminals that are different from one another, and the inductor is connected between the ground terminals to which the foregoing two terminals are connected.

An amplifier circuit according to one aspect of the present disclosure includes an input terminal, an output terminal, a first transistor provided in between the input terminal and the output terminal, a second transistor provided in between the input terminal and the output terminal, the second transistor being connected to the first transistor in a multistage manner, and a coiled or meandered inductor. The first transistor has a first control terminal, a first terminal, and a second terminal, the second transistor has a second control terminal, a third terminal, and a fourth terminal, of the first control terminal, the second control terminal, the first terminal, the second terminal, the third terminal, and the fourth terminal, two terminals are connected to ground terminals that are different from one another, and the inductor is connected between the ground terminals to which the foregoing two terminals are connected.

According to the present disclosure, it becomes possible to realize an amplifier circuit that facilitates both the ESD protection and the oscillation suppression.

### BRIEF DESCRIPTION OF THE DRAWINGS

FIG. 1 is a circuit configuration diagram illustrating an example of an amplifier circuit according to an embodiment 1.

FIG. 2A is a diagram illustrating an example of an inductor to be connected between ground terminals.

FIG. 2B is a diagram illustrating an example of the inductor to be connected between the ground terminals.

FIG. 2C is a diagram illustrating an example of the inductor to be connected between the ground terminals.

FIG. 2D is a diagram illustrating an example of the inductor to be connected between the ground terminals.

FIG. 2E is a diagram illustrating an example of the inductor to be connected between the ground terminals.

FIG. 2F is a diagram illustrating an example of the inductor to be connected between the ground terminals.

FIG. 3 is a diagram illustrating an example of the inductor to be connected between the ground terminals.

FIG. 4 is a diagram illustrating an example of the inductor to be connected between the ground terminals.

FIG. 5A is a diagram illustrating an example of the inductor to be connected between the ground terminals.

FIG. 5B is a diagram illustrating an example of the inductor to be connected between the ground terminals.

FIG. 5C is a diagram illustrating an example of the inductor to be connected between the ground terminals.

FIG. 5D is a diagram illustrating an example of the inductor to be connected between the ground terminals.

FIG. 5E is a diagram illustrating an example of the inductor to be connected between the ground terminals.

FIG. 5F is a diagram illustrating an example of the inductor to be connected between the ground terminals.

FIG. 5G is a diagram illustrating an example FIG. 5G is a diagram illustrating an example of the inductor to be connected between the ground terminals.

FIG. 6 is a sectional view illustrating an example of mounting of an amplifier circuit according to the embodiment 1.

FIG. 7 is a circuit configuration diagram illustrating an example of an amplifier circuit according to an embodiment 2.

FIG. 8 is a circuit configuration diagram illustrating an example of an amplifier circuit according to an embodiment 3.

FIG. 9 is a circuit configuration diagram illustrating an example of an amplifier circuit according to another embodiment.

### DETAILED DESCRIPTION

### Details That Led to One Aspect of the Present Disclosure

First, details that led to one aspect of the present disclosure are described.

At the time of mounting a semiconductor package, in which an amplifier circuit is formed, on a module or the like, electric potential differences between terminals of the semiconductor package are not fixed, and high voltages are likely to be applied across the terminals due to ESD or the like. Because of this, an antiparallel diode is provided as the ESD protection element, and this suppresses the application of a high voltage across the terminals due to ESD or the like.

However, the ESD protection element such as the one described above has a series capacitance component for a radio frequency signal having a small amplitude, for which the ESD protection element is not electrically continuous. Further, a ground terminal, to which a terminal of the semiconductor package is connected, has a certain ground impedance component when grounded.

The series capacitance component formed between the ground terminals and the ground impedance components thereof form a circuit similar to a L-C-L π-type HPF (High Pass Filter), and radio frequency signals having frequencies higher than a certain frequency pass between the ground terminals via the ESD protection element. As a result, it becomes difficult for the amplifier circuit to realize desired electric characteristics. Specifically, the frequency characteristic of the amplifier circuit is likely to deviate from a desired characteristic. Moreover, because of the formation of a return path of a radio frequency signal by a circuit network formed by these inductance components and capacitance components, the gain of the amplifier circuit may decrease, and an oscillation may occur. In recent years, particularly, semiconductor elements or compound semiconductor elements having SOI (Silicon On Insulator) structures are being used. Because of this, amplifying elements are having higher gains at higher frequencies, and oscillations are likely to occur.

As described above, the provision of an ESD protection element for improving the tolerance against ESD may pose a risk of oscillation.

In the following section, an amplifier circuit that facilitates both the ESD protection and the oscillation suppression is described.

Hereinafter, embodiments of the present disclosure will be described in detail with reference to the drawings. Note that the embodiments, which will be described below, each illustrate a comprehensive or specific example. Numeric values, shapes, materials, constituent elements, arrangements and connection modes of the constituent elements, and the like illustrated in the following embodiments are mere examples, and not intended to limit the present disclosure. Of constituent elements in the following embodiments, the constituent elements that are not described in an independent claim will be described as optional constituent elements. Further, sizes or ratios of the sizes of constituent elements illustrated in the drawings are not necessarily exact ones. Further, in the respective drawings, same reference characters are attached to substantially the same constituent elements, and in some cases, overlapping descriptions are omitted or simplified. Further, in the following embodiments, the term “connect” is defined to include not only the case where elements are connected directly but also the case where elements are electrically connected via another element (for example, a capacitor, an inductor, a semiconductor element, such as a diode, a transistor, or the like, or any other similar element). Further, for example, the term “to be connected between A and B” is defined to mean to be connected between A and B while being connected to both A and B directly or via another element. For example, the term “to be connected between (two) ground terminals” is defined to mean to be connected between one ground terminal and another ground terminal while being connected to both the one ground terminal and another ground terminal directly or via another element.

### Embodiment 1

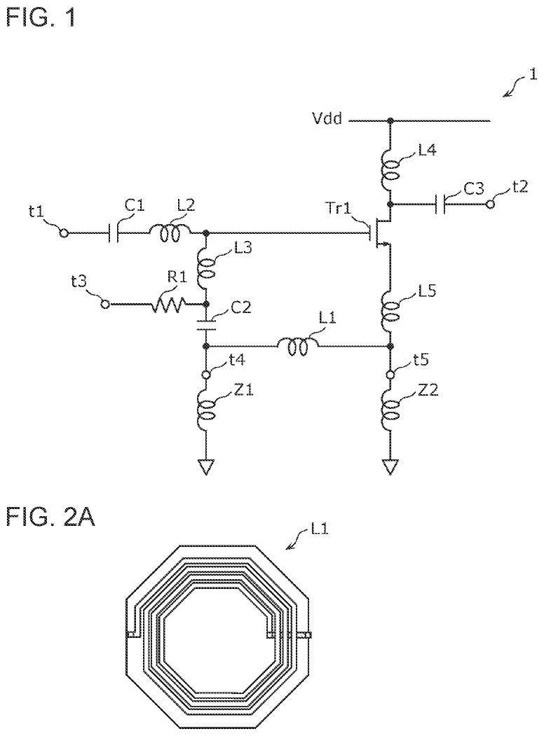

The embodiment 1 is described using FIG. 1 to FIG. 6.

[Circuit Configuration]

FIG. 1 is a circuit configuration diagram illustrating an example of an amplifier circuit 1 according to the embodiment 1.

The amplifier circuit 1 is a circuit that amplifies an input radio frequency signal and outputs an amplified radio frequency signal. The amplifier circuit 1 may be a LNA (Low Noise Amplifier) or a PA (Power Amplifier). The amplifier circuit 1 includes an input terminal t1, an output terminal t2, and a bias terminal t3. The input terminal t1 is a terminal to which a radio frequency signal is input, and the output terminal t2 is a terminal from which an amplified radio frequency signal is output. The bias terminal t3 is a terminal to which a bias is input. Note that ground terminals t4 and t5 may be constituent elements of the amplifier circuit 1 or do not necessarily need to be constituent elements of the amplifier circuit 1. That is to say, the amplifier circuit 1 may include the ground terminals t4 and t5 or does not necessarily need to include the ground terminals t4 and t5. The ground terminals t4 and t5 are terminals to be connected to the ground such as a ground plane electrode of a substrate of the module (main board or the like) or the like and are also terminals for grounding particular terminals of the amplifier circuit 1.

The amplifier circuit 1 includes a transistor Tr1, inductors L1, L2, L3, L4, and L5, capacitors C1, C2, and C3, and a resistor R1.

The transistor Tr1 is an example of a first transistor provided in between the input terminal t1 and the output terminal t2. Specifically, the transistor Tr1 is arranged in a path connecting the input terminal t1 and the output terminal t2. The transistor Tr1 is, for example, formed in a semiconductor layer. The transistor Tr1 has a first control terminal, a first terminal, and a second terminal. The first control terminal is a gate or a base, the first terminal is a source or an emitter, and the second terminal is a drain or a collector. For example, the transistor Tr1 is a FET (Field Effect Transistor), and in this case, the first control terminal is the gate, the first terminal is the source, and the second terminal is the drain.

Of the gate, the source, and the drain of the transistor Tr1, two terminals are connected to ground terminals that are different from each other. Here, these two terminals of the transistor Tr1 are the gate and the source. The gate of the transistor Tr1 is connected to the ground terminal t4, and the source of the transistor Tr1 is connected to the ground terminal t5. Specifically, the gate of the transistor Tr1 is connected to the ground terminal t4 via the inductor L3 and the capacitor C2, and the source of the transistor Tr1 is connected to the ground terminal t5 via the inductor L5.

Further, the gate of the transistor Tr1 is connected to the input terminal t1 via the inductor L2 and the capacitor C1 and to the bias terminal t3 via the inductor L3 and the resistor R1. The drain of the transistor Tr1 is connected to the output terminal t2 via the capacitor C3 and to a power Vdd via the inductor L4.

The inductor L1 is connected between the ground terminals to which the foregoing two terminals are connected. Here, the inductor L1 is connected between the ground terminal t4 to which the gate of the transistor Tr1 is connected and the ground terminal t5 to which the source of the transistor Tr1 is connected. The inductor L1 connected between the ground terminals t4 and t5 is a coiled or meandered inductor. Exemplary shapes of the coiled or meandered inductor will be described below.

The capacitor C1 is arranged in a path connecting the gate of the transistor Tr1 and the input terminal t1. The capacitor C1 constitutes an input matching circuit for matching the input impedance of the transistor Tr1. Further, the capacitor C1 functions as a DC-cut capacitor that prevents a bias, which is input to the bias terminal t3, from leaking to the input terminal t1.

The inductor L2 is arranged in the path connecting the gate of the transistor Tr1 and the input terminal t1 and is connected in series to the capacitor C1. The inductor L2 constitutes the input matching circuit for matching the input impedance of the transistor Tr1.

The inductor L3 is connected between the ground terminal t4 and a node in the path connecting the gate of the transistor Tr1 and the input terminal t1. The inductor L3 constitutes the input matching circuit for matching the input impedance of the transistor Tr1.

The capacitor C2 is connected in series to the inductor L3 between the ground terminal t4 and a node in the path connecting the gate of the transistor Tr1 and the input terminal t1. The capacitor C2 constitutes the input matching circuit for matching the input impedance of the transistor Tr1. Further, the capacitor C2 functions as a DC-cut capacitor that prevents the bias, which is input to the bias terminal t3, from leaking to the ground terminal t4.

The resistor R1 is arranged in a path connecting the gate of the transistor Tr1 and the bias terminal t3. The resistor R1 functions as a resistor that prevents a radio frequency signal, which is input to the input terminal t1, from leaking to the bias terminal t3.

The capacitor C3 is arranged in a path connecting the drain of the transistor Tr1 and the output terminal t2. The capacitor C3 constitutes an output matching circuit for matching the output impedance of the transistor Tr1. Further, the capacitor C3 also functions as a DC-cut capacitor that prevents a direct current from the power Vdd from leaking to the output terminal t2.

The Inductor L4 is arranged in a path connecting the drain of the transistor Tr1 and the power Vdd. The inductor L4 constitutes the output matching circuit for matching the output impedance of the transistor Tr1.

The Inductor L5 is arranged in a path connecting the source of the transistor Tr1 and the ground terminal t5. The inductor L5 is a source degeneration inductor for improving linearity of the transistor Tr1.

A ground impedance component Z1 is a ground impedance component of the ground terminal t4, and a ground impedance component Z2 is a ground impedance component of the ground terminal t5. The ground impedance components will be described below.

Note that here, there is described the example in which two terminals of the gate, the source, and the drain of the transistor Tr1 are connected to the ground terminals that are different from each other. Alternatively, of the gate, the source, and the drain of the transistor Tr1, at least two terminals may be connected to the ground terminals that are different from each other. In other words, each of the gate, the source, and the drain of the transistor Tr1 may be connected to a different ground terminal.

Further, another element may be connected to the inductor L1 between the ground terminals t4 and t5. For example, between the ground terminals t4 and t5, the inductor L1 may be connected to another element in series or in parallel.

Further, the transistor Tr1 may alternatively be a bipolar transistor. In this case, the first control terminal is the base, the first terminal is the emitter, and the second terminal is the collector. In the foregoing description and the following description, the gate may be replaced with the base, the source may be replaced with the emitter, and the drain may be replaced with the collector.

### Specific Examples of Coiled or Meandered Inductor

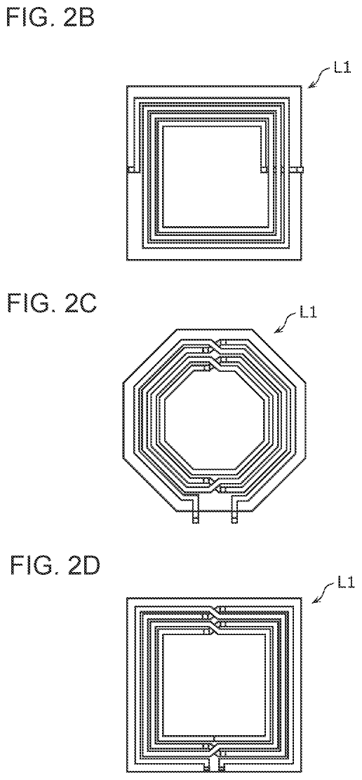

Next, specific examples of the coiled or meandered inductor L1 will be described using FIG. 2A to FIG. 5G.

FIG. 2A to FIG. 5G are diagrams each illustrating an example of the inductor L1 connected between the ground terminals t4 and t5.

FIG. 2A to FIG. 2F are diagrams each illustrating a specific example of the coiled (specifically, spiral form) inductor L1.

As illustrated in FIG. 2A and FIG. 2B, the inductor L1 may be defined in such a manner as to have a concentric form in a plurality of layers. As illustrated in FIG. 2C and FIG. 2D, the inductor L1 may be defined in such a manner as to have a concentric form with bilateral symmetry as much as possible in a plurality of layers. As illustrated in FIG. 2E and FIG. 2F, the inductor L1 may be defined in such a manner as to have a concentric form across a plurality of layers. Specifically, in each of FIG. 2A to FIG. 2F, a wiring line or lines without necessarily hatching are defined in a layer or layers on the front side thereof, and a wiring line or lines with hatching are defined in a layer or layers on the back side thereof.

For example, the inductor L1 is defined in such a manner as to have a polygonal shape (octagon in FIG. 2A, FIG. 2C, and FIG. 2E, and quadrilateral in FIG. 2B, FIG. 2D, and FIG. 2F). However, depending on processes, the inductor L1 may be defined in such a manner as to have a circle shape with no corner.

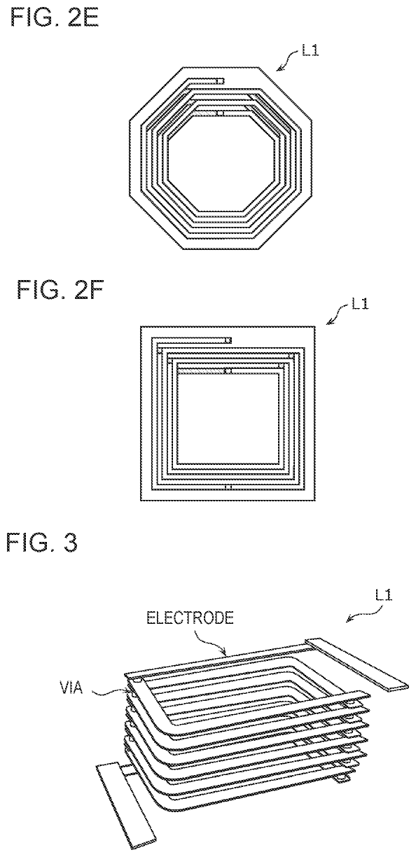

FIG. 3 is a diagram illustrating a specific example of the coiled inductor L1. In FIG. 3, electrodes defined in respective layers and vias are illustrated, and dielectric layers and the like are made to be transparent.

As illustrated in FIG. 3, by connecting end portions of the electrodes defined in the respective layers with the vias, the electrodes of the respective layers and the vias may collectively form the coiled inductor L1.

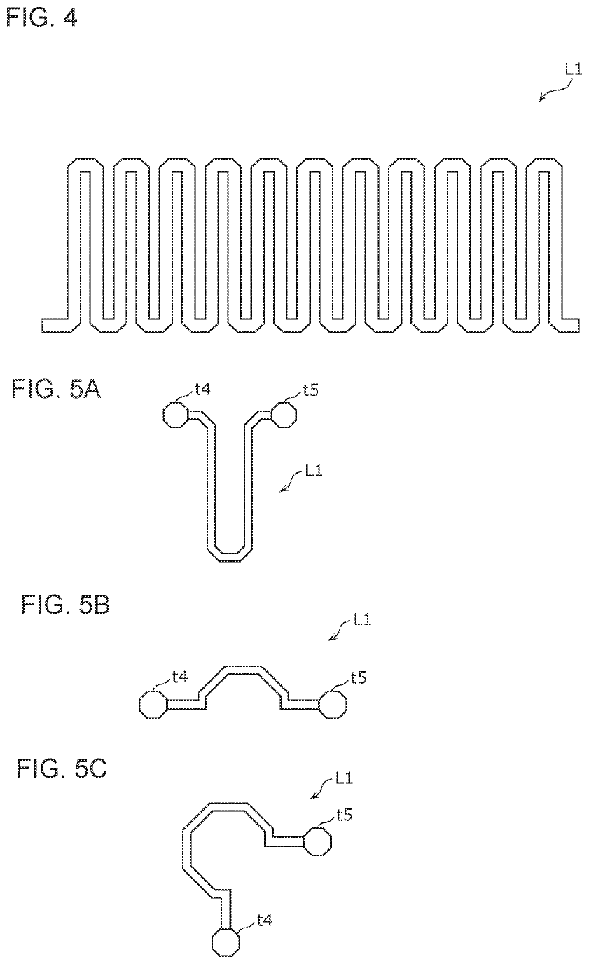

FIG. 4 is a diagram illustrating a specific example of the meandered inductor L1.

As illustrated in FIG. 4, the inductor L1 may be defined to have a meandered form.

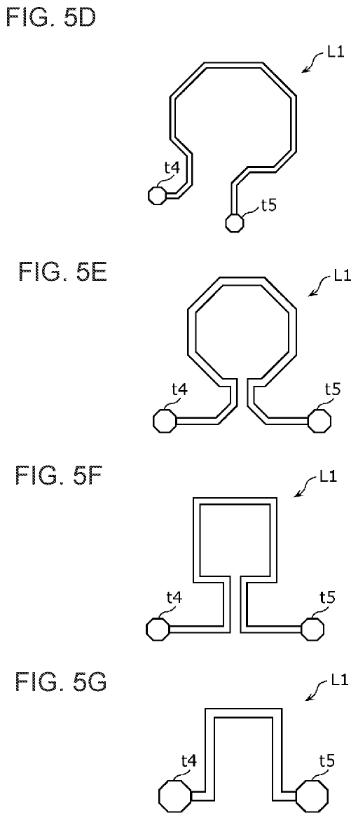

FIG. 5A to FIG. 5G are diagrams each illustrating a specific example of the coiled or meandered inductor L1.

In FIG. 2A to FIG. 2F and FIG. 3, as the coiled inductor L1, the inductor formed by winding a wiring line one or more turns is illustrated. However, the coiled inductor L1 is not necessarily formed by winding a wiring line one or more turns and may alternatively be formed of a wiring line that is wound less than one turn, as illustrated in FIG. 5B, FIG. 5C, FIG. 5D, FIG. 5E, and FIG. 5F. Further, as the meandered inductor L1, FIG. 4 illustrates the inductor formed with a pattern in which a wiring line extends back and forth twice or more. However, the meandered inductor L1 is not necessarily formed with the pattern in which a wiring line extends back and forth twice or more and may alternatively be formed with a pattern in which a wiring line extends back and forth only once, as illustrated in FIG. 5A and FIG. 5G. In either shape, it is desirable that the length of the wiring line forming the inductor L1 is longer than the straight-line distance between the ground terminals t4 and t5.

[Ground Impedance Component]

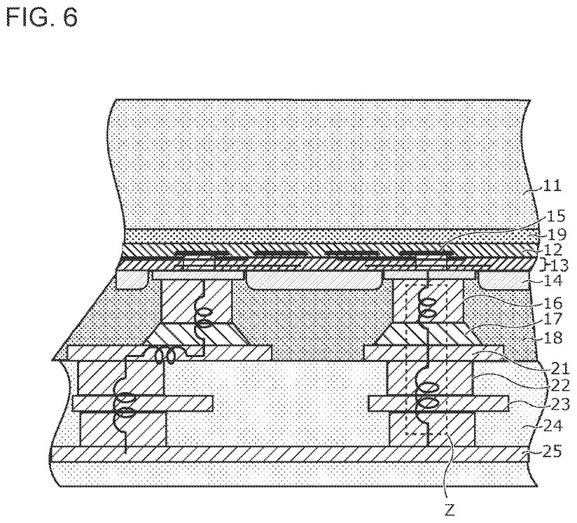

Next, the ground impedance component is described using FIG. 6.

FIG. 6 is a sectional view illustrating an example of mounting of the amplifier circuit 1 according to the embodiment 1.

Regarding the semiconductor package in which the amplifier circuit 1 is formed, a semiconductor substrate 11 is, for example, a silicon substrate, and a body 15 of the transistor Tr1 or the like is formed in a semiconductor layer 12 arranged on the semiconductor substrate 11 (here, on a buried oxide layer 19). For example, the inductor L1 is formed in a wiring layer 13 that is provided on the semiconductor substrate 11.

The gate, the source, or the drain of the transistor Tr1 in the body 15 are connected to copper pillars 16. The copper pillar 16 is an example of the ground terminal. The copper pillar 16 is connected to a surface layer electrode 21 of the substrate of the module with a reflowed solder bump 17 interposed therebetween. A space between an insulator 14 that lies on a surface of the semiconductor package and a surface of the substrate of the module is filled with a mold resin 18, and the copper pillars 16 and the solder bumps 17 are covered with the mold resin 18.

In a dielectric layer 24 of the substrate of the module, vias 22, internal layer electrodes 23, and a ground plane electrode 25 are provided, and the surface layer electrode 21 is connected to the ground plane electrode 25 with the via 22, the internal layer electrode 23, and the like interposed therebetween. Because the ground plane electrode 25 is connected to the ground, the copper pillar 16 connected to the surface layer electrode 21 is grounded.

The ground impedance component Z includes an inductance component of the copper pillar 16 and the solder bump 17, a wiring inductance component of a bonding wire, a wiring inductance component of the module on which the semiconductor package, in which the amplifier circuit 1 is formed, is mounted, a wiring inductance component of a substrate of the semiconductor package or a RF (Radio Frequency) device, and the like.

### Effects

The amplifier circuit 1 includes the input terminal t1, the output terminal t2, the transistor Tr1 provided in between the input terminal t1 and the output terminal t2, and the coiled or meandered inductor L1. The transistor Tr1 has the gate, the source, and the drain, and of these gate, source, and drain, two terminals are connected to the ground terminals t4 and t5 that are different from each other. The inductor L1 is connected between the ground terminals t4 and t5 to which the foregoing two terminals are connected.

According to this, the inductor L1 is connected between the ground terminals t4 and t5, and thus, at the time of mounting the amplifier circuit 1 on the module, the RF device, or the like, it become possible to fix the electric potentials of the ground terminals t4 and t5 at the same electric potential by using the inductor L1. Accordingly, it becomes possible to suppress the generation of a large electric potential difference between the terminals of the transistor Tr1 due to ESD or the like, and the reliability of the amplifier circuit 1 can be improved. For example, in the case where the two terminals of the transistor Tr1 that are connected to the ground terminals t4 and t5 are the gate and the source, the electric potential difference between the gate and the source is less likely to increase, and the transistor Tr1 is less likely to be damaged by ESD.

Further, although the ground terminals t4 and t5 will have certain ground impedance components when the ground terminals t4 and t5 are grounded, because the inductor L1 has a coiled form or a meandered form, the inductance value of the inductor L1 can be made larger than the ground impedance component (specifically, the inductance component). According to this, it becomes possible to suppress the passage of a radio frequency signal between the ground terminals t4 and t5 via the inductor L1. Further, it becomes possible to suppress the variation of the electric potential across the ground terminals t4 and t5.

The provision of the inductor L1 such as the one described above facilitates the realization of desired electric characteristics of the amplifier circuit 1 as designed. Specifically, the provision of the inductor L1 such as the one described above makes it easy to set the frequency characteristic of gain of the amplifier circuit 1 to a desired characteristic. Moreover, because the feedback of a radio frequency signal is less likely to happen, the gain of the amplifier circuit 1 is less likely to decrease, and further, oscillations can be suppressed. For example, even with the amplifier circuit 1 that uses a semiconductor element employing a SOI structure or a compound semiconductor element composed of GaAs, SiGe, GaN, or the like and has a high gain at a high frequency, the provision of the inductor L1 such as the one described above makes it easy to suppress the occurrence of an unexpected shortcoming such as an oscillation at a frequency outside a desired band while delivering available performance. Note that in the amplifier circuit 1, a semiconductor element that employs a SOS (Silicon On Sapphire) structure may alternatively be used. Further, the semiconductor element may alternatively be a bulk CMOS (Complementary Metal Oxide Semiconductor) and the like.

As described above, by connecting the coiled or meandered inductor L1 between the ground terminals t4 and t5 to which the two terminals of the transistor Tr1 are connected, it becomes possible to realize the amplifier circuit 1 that facilitates both the ESD protection and the oscillation suppression. Further, because the inductor L1 is not an element that can be damaged by ESD, it becomes possible to provide a highly reliable ESD protection.

For example, the inductor L1 may alternatively be formed in the wiring layer 13 that is provided on the semiconductor substrate 11.

The inductor L1 is provided for ESD protection and not for allowing a radio frequency signal to pass, and thus the Q factor thereof is not necessarily high. Because of this, the inductor L1 may be formed of a thin wiring line or may be formed in such a manner as not to secure a large gap for a radio frequency magnetic path. Accordingly, in the case where the inductor L1 is formed in the wiring layer 13 that is provided on the semiconductor substrate 11, the inductor L1 can be a small inductor. Thus, both the size and the cost of the amplifier circuit 1 can be reduced.

### Embodiment 2

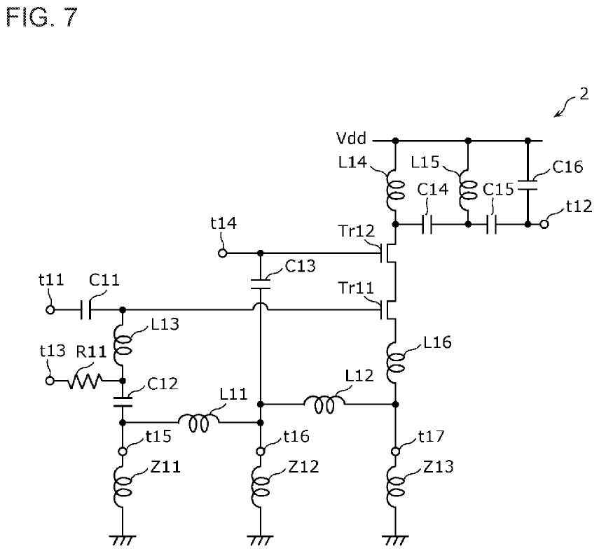

Next, the embodiment 2 is described with reference to FIG. 7.

[Circuit Configuration]

FIG. 7 is a circuit configuration diagram illustrating an example of an amplifier circuit 2 according to the embodiment 2.

The amplifier circuit 2 is a circuit that amplifies an input radio frequency signal and outputs an amplified radio frequency signal. The amplifier circuit 2 is, for example, a LNA and may alternatively be a PA. The amplifier circuit 2 includes an input terminal t11, an output terminal t12, and bias terminals t13 and t14. The input terminal t11 is a terminal to which a radio frequency signal is input, and the output terminal t12 is a terminal from which an amplified radio frequency signal is output. The bias terminals t13 and t14 are terminals to which biases are input. Note that ground terminals t15, t16, and t17 may be constituent elements of the amplifier circuit 2 or do not necessarily need to be constituent elements of the amplifier circuit 2. That is to say, the amplifier circuit 2 may include the ground terminals t15, t16, and t17 or does not necessarily need to include the ground terminals t15, t16, and t17. The ground terminals t15, t16, and t17 are terminals to be connected to the ground such as a ground plane electrode of a substrate of the module (main board or the like) or the like and are also terminals for grounding particular terminals of the amplifier circuit 2.

The amplifier circuit 2 includes transistors Tr11 and Tr12, inductors L11, L12, L13, L14, L15, and L16, capacitors C11, C12, C13, C14, C15, and C16, and a resistor R11.

The transistor Tr1 is an example of the first transistor provided in between the input terminal t11 and the output terminal t12. The transistor Tr1 is, for example, formed in a semiconductor layer. The transistor Tr11 has a first control terminal, a first terminal, and a second terminal. The first control terminal is a gate or a base, the first terminal is a source or an emitter, and the second terminal is a drain or a collector. For example, the transistor Tr1 is a FET, and in this case, the first control terminal is the gate, the first terminal is the source, and the second terminal is the drain.

The transistor Tr12 is an example of a second transistor that is provided in between the input terminal t11 and the output terminal t12 and is connected to the transistor Tr1 in a multistage manner. Here, the transistor Tr1 and the transistor Tr12 are connected to each other in a cascode configuration and form a cascode amplifier. The transistor Tr12 is, for example, formed in the semiconductor layer. The transistor Tr12 has a second control terminal, a third terminal, and a fourth terminal. The second control terminal is a gate or a base, the third terminal is a source or an emitter, and the fourth terminal is a drain or a collector. For example, the transistor Tr12 is a FET, and in this case, the second control terminal is the gate, the third terminal is the source, and the fourth terminal is the drain.

Of the gate, the source, and the drain of the transistor Tr11 and the gate, the source, and the drain of the transistor Tr12, two terminals are connected to the ground terminals that are different from each other. These two terminals of the transistor Tr11 may be the gate and the source. The gate of the transistor Tr11 may be connected to the ground terminal t15, and the source of the transistor Tr11 may be connected to the ground terminal t17. In this case, specifically, the gate of the transistor Tr11 is connected to the ground terminal t15 via the inductor L13 and the capacitor C12, and the source of the transistor Tr11 is connected to the ground terminal t17 via the inductor L16.

Further, these two terminals may include one terminal of the gate, the source, and the drain of the transistor Tr11 and one terminal of the gate, the source, and the drain of the transistor Tr12. These two terminals may be the gate of the transistor Tr11 and the gate of the transistor Tr12. The gate of the transistor Tr11 may be connected to the ground terminal t15, and the gate of the transistor Tr12 may be connected to the ground terminal t16. In this case, specifically, the gate of the transistor Tr11 is connected to the ground terminal t15 via the inductor L13 and the capacitor C12, and the gate of the transistor Tr12 is connected to the ground terminal t16 via the capacitor C13. Alternatively, these two terminals may be the source of the transistor Tr11 and the gate of the transistor Tr12. The source of the transistor Tr11 may be connected to the ground terminal t17, and the gate of the transistor Tr12 may be connected to the ground terminal t16. In this case, specifically, the source of the transistor Tr11 is connected to the ground terminal t17 via the inductor L16, and the gate of the transistor Tr12 is connected to the ground terminal t16 via the capacitor C13.

Further, the gate of the transistor Tr11 is connected to the input terminal t11 via the capacitor C11 and to the bias terminal t13 via the inductor L13 and the resistor R11. The drain of the transistor Tr11 is connected to the source of the transistor Tr12.

Further, the gate of the transistor Tr12 is connected to the bias terminal t14. The drain of the transistor Tr12 is connected to the output terminal t12 via the capacitors C14 and C15 and to a power Vdd via the inductor L14.

The inductor L11 is connected between the ground terminal t15 to which the gate of the transistor Tr11 is connected and the ground terminal t16 to which the gate of the transistor Tr12 is connected. The inductor L11 connected between the ground terminals t15 and t16 is a coiled or meandered inductor. Exemplary shapes of the coiled or meandered inductor L11 are the same as those of the inductor L1 described in the embodiment 1, and thus the descriptions thereof are omitted.

The inductor L12 is connected between the ground terminal t16 to which the gate of the transistor Tr12 is connected and the ground terminal t17 to which the source of the transistor Tr11 is connected. The inductor L12 connected between the ground terminals t16 and t17 is a coiled or meandered inductor. Exemplary shapes of the coiled or meandered inductor L12 are the same as those of the inductor L1 described in the embodiment 1, and thus the descriptions thereof are omitted.

Note that here, the example is described for the case where two inductors, which are the inductors L11 and L12, are connected between the ground terminal t15 to which the gate of the transistor Tr1 is connected and the ground terminal t17 to which the source of the transistor Tr1 is connected. However, only a single coiled or meandered inductor may be connected between the ground terminals t15 and t17.

The capacitor C11 is arranged in a path connecting the gate of the transistor Tr1 and the input terminal t11. The capacitor C11 constitutes an input matching circuit for matching the input impedance of the transistor Tr1. Further, the capacitor C11 functions as a DC-cut capacitor that prevents a bias, which is input to the bias terminal t13, from leaking to the input terminal t11.

The inductor L13 is connected between the ground terminal t15 and a node in the path connecting the gate of the transistor Tr1 and the input terminal t11. The inductor L13 constitutes the input matching circuit for matching the input impedance of the transistor Tr1.

The capacitor C12 is connected in series to the inductor L13 between the ground terminal t15 and a node in the path connecting the gate of the transistor Tr1 and the input terminal t11. The capacitor C12 constitutes the input matching circuit for matching the input impedance of the transistor Tr11. Further, the capacitor C12 functions as a DC-cut capacitor that prevents the bias, which is input to the bias terminal t13, from leaking to the ground terminal t15.

The resistor R11 is arranged in a path connecting the gate of the transistor Tr11 and the bias terminal t13. The resistor R11 functions as a resistor that prevents a radio frequency signal, which is input to the input terminal t11, from leaking to the bias terminal t13.

The capacitor C13 is connected between the ground terminal t16 and a node in a path connecting the gate of the transistor Tr12 and the bias terminal t14. The capacitor C13 functions as a DC-cut capacitor that prevents a bias, which is input to the bias terminal t14, from leaking to the ground terminal t16.

The capacitor C14 is arranged in a path connecting the drain of the transistor Tr12 and the output terminal t12. The capacitor C14 constitutes an output matching circuit for matching the output impedance of the transistor Tr12. Further, the capacitor C14 also functions as a DC-cut capacitor that prevents a direct current from the power Vdd from leaking to the output terminal t12.

The capacitor C15 is connected in series to the capacitor C14 in the path connecting the drain of the transistor Tr12 and the output terminal t12. The capacitor C15 constitutes the output matching circuit for matching the output impedance of the transistor Tr12. Further, the capacitor C15 also functions as a DC-cut capacitor that prevents a direct current from the power Vdd from leaking to the output terminal t12.

The capacitor C16 is connected between the power Vdd and a node in a path connecting the capacitor C15 and the output terminal t12. The capacitor C16 constitutes the output matching circuit for matching the output impedance of the transistor Tr12. Further, the capacitor C16 also functions as a DC-cut capacitor that prevents a direct current from the power Vdd from leaking to the output terminal t12.

The Inductor L14 is arranged in a path connecting the drain of the transistor Tr12 and the power Vdd. The inductor L14 constitutes the output matching circuit for matching the output impedance of the transistor Tr12.

The inductor L15 is connected between the power Vdd and a node in a path connecting the capacitor C14 and the capacitor C15. The inductor L15 constitutes the output matching circuit for matching the output impedance of the transistor Tr12.

The Inductor L16 is arranged in a path connecting the source of the transistor Tr11 and the ground terminal t17. The inductor L16 is a source degeneration inductor for improving linearity of the transistor Tr11.

A ground impedance component Z11 is a ground impedance component of the ground terminal t15, a ground impedance component Z12 is a ground impedance component of the ground terminal t16, and a ground impedance component Z13 is a ground impedance component of the ground terminal t17. The ground impedance components have been described in the embodiment 1, and thus, the descriptions thereof are omitted.

Note that another element may be connected to the inductor L11 between the ground terminals t15 and t16, and another element may be connected to the inductor L12 between the ground terminals t16 and t17. For example, another element may be connected to the inductor L11 in series or in parallel between the ground terminals t15 and t16, and another element may be connected to the inductor L12 in series or in parallel between the ground terminals t16 and t17.

Further, the transistor Tr11 may alternatively be a bipolar transistor. In this case, the first control terminal is the base, the first terminal is the emitter, and the second terminal is the collector. Further, the transistor Tr12 may alternatively be a bipolar transistor. In this case, the second control terminal is the base, the third terminal is the emitter, and the fourth terminal is the collector. In the foregoing description and the following description, the gate may be replaced with the base, the source may be replaced with the emitter, and the drain can may be replaced with the collector.

### Effects

The amplifier circuit 2 includes the input terminal t11, the output terminal t12, the transistor Tr11 provided in between the input terminal t11 and the output terminal t12, the transistor Tr12 that is provided in between the input terminal t11 and the output terminal t12 and is connected to the transistor Tr11 in a multistage manner, and the coiled or meandered inductors L11 and L12. The transistor Tr11 has the gate, the source, and the drain, and the transistor Tr12 has the gate, the source, and the drain. Of the gate, the source, and the drain of the transistor Tr11 and the gate, the source, and the drain of the transistor Tr12, two terminals are connected to the ground terminals t15, t16, and t17 that are different from each other. The inductors L11 and L12 are connected between the ground terminals to which the foregoing two terminals are connected (specifically, the inductor L11 is connected between the ground terminals t15 and t16, and the inductor L12 is connected between the ground terminals t16 and t17).

For example, the foregoing two terminals may include one of the gate, the source, and the drain of the transistor Tr11 and one of the gate, the source, and the drain of the transistor Tr12.

As is the case with the amplifier circuit 1 according to the embodiment 1, also in the embodiment 2, it becomes possible to realize the amplifier circuit 2 that facilitates both the ESD protection and the oscillation suppression. Further, in the amplifier circuit 2 made up of the transistors connected in a multistage manner, the number of ground points increases compared with the amplifier circuit made up of a single transistor. With semiconductor packages for RF, in the case where a single common ground terminal is used, harmful actions such as a gain decrease, an oscillation, and the like are likely to happen. Thus, a plurality of independent ground terminals (bumps or the like) is provided in many cases. As a result, a large number of the ground terminals have been provided, and this increases the likelihood of amplifier circuit failure caused by harmful voltages such as ESD and the like applied across these ground terminals. Because of this, the ESD countermeasure using the inductor of the present disclosure becomes effective for the amplifier circuit 2 that has a high likelihood of failure because of a great number of ground points.

Further, the amplifier circuit 2 made up of the transistors that are connected in a multistage manner has a relatively high total gain, and in the case where a radio frequency signal unnecessarily passes through a large number of the ground terminals, this higher gain increases the likelihood of oscillation. With the ESD countermeasure using the inductor of the present disclosure, it becomes possible to suppress optional passage of a radio frequency signal through a large number of the ground terminals, and thus oscillations can be suppressed even in the amplifier circuit 2 that has a higher gain.

Further, a cascode amplifier makes it easy to obtain a higher gain while avoiding a mirror effect up to a high frequency band. Thus, with the amplifier circuit 2 made up of the cascode amplifier to which the present disclosure is applied, it becomes possible to realize higher reliability because of higher ESD resistivity and oscillation suppression while maintaining the original gain performance and frequency characteristic.

### Embodiment 3

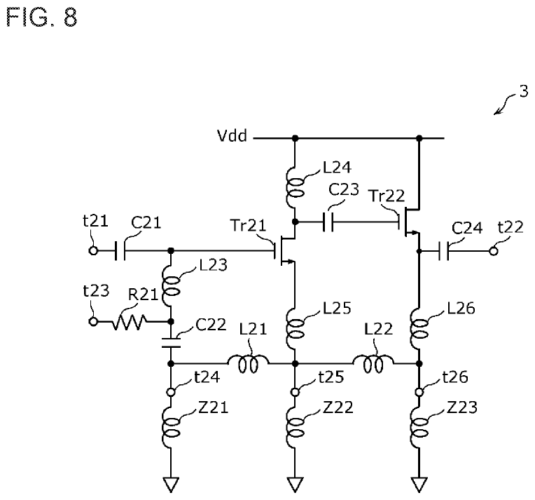

Next, the embodiment 3 is described with reference to FIG. 8.

[Circuit Configuration]

FIG. 8 is a circuit configuration diagram illustrating an example of an amplifier circuit 3 according to the embodiment 3.

The amplifier circuit 3 is a circuit that amplifies an input radio frequency signal and outputs an amplified radio frequency signal. The amplifier circuit 3 is, for example, a PA and may alternatively be an LNA. The amplifier circuit 3 includes an input terminal t21, an output terminal t22, and a bias terminal t23. The input terminal t21 is a terminal to which a radio frequency signal is input, and the output terminal t22 is a terminal from which an amplified radio frequency signal is output. The bias terminal t23 is a terminal to which a bias is input. Note that ground terminals t24, t25, and t26 may be constituent elements of the amplifier circuit 3 or do not necessarily need to be constituent elements of the amplifier circuit 3. That is to say, the amplifier circuit 3 may include the ground terminals t24, t25, and t26 or does not necessarily need to include the ground terminals t24, t25, and t26. The ground terminals t24, t25, and t26 are terminals to be connected to the ground such as a ground plane electrode of a substrate of the module (main board or the like) or the like and are also terminals for grounding particular terminals of the amplifier circuit 3.

The amplifier circuit 3 includes transistors Tr21 and Tr22, inductors L21, L22, L23, L24, L25, and L26, capacitors C21, C22, C23, and C24, and a resistor R21.

The transistor Tr21 is an example of the first transistor provided in between the input terminal t21 and the output terminal t22. The transistor Tr21 is, for example, formed in a semiconductor layer. The transistor Tr21 has a first control terminal, a first terminal, and a second terminal. The first control terminal is a gate or a base, the first terminal is a source or an emitter, and the second terminal is a drain or a collector. For example, the transistor Tr21 is a FET, and in this case, the first control terminal is the gate, the first terminal is the source, and the second terminal is the drain.

The transistor Tr22 is an example of a second transistor that is provided in between the input terminal t21 and the output terminal t22 and is connected to the transistor Tr21 in a multistage manner. Here, the transistor Tr21 is a common source transistor, and the transistor Tr22 is a source follower transistor. By connecting the drain of the transistor Tr21 to the gate of the transistor Tr22, the transistor Tr21 and the transistor Tr22 are connected to each other in a multistage manner. The transistor Tr22 is, for example, formed in a semiconductor layer. The transistor Tr22 has a second control terminal, a third terminal, and a fourth terminal. The second control terminal is a gate or a base, the third terminal is a source or an emitter, and the fourth terminal is a drain or a collector. For example, the transistor Tr22 is a FET, and in this case, the second control terminal is the gate, the third terminal is the source, and the fourth terminal is the drain.

Of the gate, the source, and the drain of the transistor Tr21 and the gate, the source, and the drain of the transistor Tr22, two terminals are connected to the ground terminals that are different from each other. These two terminals may be the gate and the source of the transistor Tr21. The gate of the transistor Tr21 may be connected to the ground terminal t24, and the source of the transistor Tr21 may be connected to the ground terminal t25. In this case, specifically, the gate of the transistor Tr21 is connected to the ground terminal t24 via the inductor L23 and the capacitor C22, and the source of the transistor Tr21 is connected to the ground terminal t25 via the inductor L25.

Further, these two terminals may include one of the gate, the source, and the drain of the transistor Tr21 and one of the gate, the source, and the drain of the transistor Tr22. These two terminals may be the gate of the transistor Tr21 and the source of the transistor Tr22. The gate of the transistor Tr21 may be connected to the ground terminal t24, and the source of the transistor Tr22 may be connected to the ground terminal t26. In this case, specifically, the gate of the transistor Tr21 is connected to the ground terminal t24 via the inductor L23 and the capacitor C22, and the source of the transistor Tr22 is connected to the ground terminal t26 via the inductor L26. Alternatively, these two terminals may be the source of the transistor Tr21 and the source of the transistor Tr22. The source of the transistor Tr21 may be connected to the ground terminal t25, and the source of the transistor Tr22 may be connected to the ground terminal t26. In this case, specifically, the source of the transistor Tr21 is connected to the ground terminal t25 via the inductor L25, and the source of the transistor Tr22 is connected to the ground terminal t26 via the inductor L26.

Further, the gate of the transistor Tr21 is connected to the input terminal t21 via the capacitor C21 and to the bias terminal t23 via the inductor L23 and the resistor R21. The drain of the transistor Tr1 is connected to the power Vdd via the inductor L24.

Further, the gate of the transistor Tr22 is connected to the drain of the transistor Tr21 via the capacitor C23 and to the power Vdd via the capacitor C23 and the inductor L24. The drain of the transistor Tr22 is connected to the power Vdd. The source of the transistor Tr22 is connected to the output terminal t22 via the capacitor C24.

The inductor L21 is connected between the ground terminal t24 to which the gate of the transistor Tr21 is connected and the ground terminal t25 to which the source of the transistor Tr21 is connected. The inductor L21 connected between the ground terminals t24 and t25 is a coiled or meandered inductor. Exemplary shapes of the coiled or meandered inductor L21 are the same as those of the inductor L1 described in the embodiment 1, and thus the descriptions thereof are omitted.

The inductor L22 is connected between the ground terminal t25 to which the source of the transistor Tr21 is connected and the ground terminal t26 to which the source of the transistor Tr22 is connected. The inductor L22 connected between the ground terminals t25 and t26 is a coiled or meandered inductor. Exemplary shapes of the coiled or meandered inductor L22 are the same as those of the inductor L1 described in the embodiment 1, and thus the descriptions thereof are omitted.

Note that here, the example is described using the case where two inductors L21 and L22 are connected between the ground terminal t24 to which the gate of the transistor Tr21 is connected and the ground terminal t26 to which the source of the transistor Tr22 is connected. Alternatively, only a single coiled or meandered inductor may be connected between the ground terminals t24 and t26.

The capacitor C21 is arranged in a path connecting the gate of the transistor Tr21 and the input terminal t21. The capacitor C21 constitutes an input matching circuit for matching the input impedance of the transistor Tr21. Further, the capacitor C21 functions as a DC-cut capacitor that prevents a bias, which is input to the bias terminal t23, from leaking to the input terminal t21.

The inductor L23 is connected between the ground terminal t24 and a node in the path connecting the gate of the transistor Tr21 and the input terminal t21. The inductor L23 constitutes the input matching circuit for matching the input impedance of the transistor Tr21.

The capacitor C22 is connected in series to the inductor L23 between the ground terminal t24 and a node in the path connecting the gate of the transistor Tr21 and the input terminal t21. The capacitor C22 constitutes the input matching circuit for matching the input impedance of the transistor Tr21. Further, the capacitor C22 functions as a DC-cut capacitor that prevents a bias, which is input to the bias terminal t23, from leaking to the ground terminal t24.

The resistor R21 is arranged in a path connecting the gate of the transistor Tr21 and the bias terminal t23. The resistor R21 is an input bias circuit for adjusting a bias to be supplied to the gate of the transistor Tr21.

The capacitor C23 is arranged in a path connecting the drain of the transistor Tr21 and the gate of the transistor Tr22. The capacitor C23 constitutes an input matching circuit for matching the input impedance of the transistor Tr22 and further constitutes an output matching circuit for matching the output impedance of the transistor Tr21. Further, the capacitor C23 also functions as a DC-cut capacitor that prevents a direct current from the power Vdd from leaking to the gate of the transistor Tr22.

The Inductor L24 is arranged in a path connecting the drain of the transistor Tr21 and the power Vdd. The inductor L24 constitutes the input matching circuit for matching the input impedance of the transistor Tr22 and further constitutes the output matching circuit for matching the output impedance of the transistor Tr21.

The capacitor C24 is arranged in a path connecting the source of the transistor Tr22 and the output terminal t22. The capacitor C24 constitutes the output matching circuit for matching the output impedance of the transistor Tr22. Further, the capacitor C24 also functions as a DC-cut capacitor that prevents a direct current from the power Vdd from leaking to the output terminal t22.

The Inductor L25 is arranged in a path connecting the source of the transistor Tr21 and the ground terminal t25. The inductor L25 is a source degeneration inductor for improving linearity of the transistor Tr21.

The Inductor L26 is arranged in a path connecting the source of the transistor Tr22 and the ground terminal t26. The inductor L26 is a source degeneration inductor for improving linearity of the transistor Tr22.

A ground impedance component Z21 is a ground impedance component of the ground terminal t24, a ground impedance component Z22 is a ground impedance component of the ground terminal t25, and a ground impedance component Z23 is a ground impedance component of the ground terminal t26. The ground impedance components have been described in the embodiment 1, and thus, the descriptions thereof are omitted.

Note that another element may be connected to the inductor L21 between the ground terminals t24 and t25, and another element may be connected to the inductor L22 between the ground terminals t25 and t26. For example, another element may be connected to the inductor L21 in series or in parallel between the ground terminals t24 and t25, and another element may be connected to the inductor L22 in series or in parallel between the ground terminals t25 and t26.

Further, the transistor Tr21 may alternatively be a bipolar transistor. In this case, the first control terminal is the base, the first terminal is the emitter, and the second terminal is the collector. Further, the transistor Tr22 may alternatively be a bipolar transistor. In this case, the second control terminal is the base, the third terminal is the emitter, and the fourth terminal is the collector. In the foregoing description and the following description, the gate may be replaced with the base, the source may be replaced with the emitter, and the drain may be replaced with the collector.

### Effects

The amplifier circuit 3 includes the input terminal t21, the output terminal t22, the transistor Tr21 provided in between the input terminal t21 and the output terminal t22, the transistor Tr22 that is provided in between the input terminal t21 and the output terminal t22 and is connected to the transistor Tr21 in a multistage manner, and the coiled or meandered inductors L21 and L22. The transistor Tr21 has the gate, the source, and the drain, and the transistor Tr22 has the gate, the source, and the drain. Of the gate, the source, and the drain of the transistor Tr21 and the gate, the source, and the drain of the transistor Tr22, two terminals are connected to the ground terminals t24, t25, and t26 that are different from each other. The inductors L21 and L22 are connected between the ground terminals to which the foregoing two terminals are connected (specifically, the inductor L21 is connected between the ground terminals t24 and t25, and the inductor L22 is connected between the ground terminals t25 and t26).

As is the case with the amplifier circuit 1 according to the embodiment 1, also in the embodiment 3, it becomes possible to realize the amplifier circuit 3 that facilitates both the ESD protection and the oscillation suppression. Further, as is the case with the amplifier circuit 2 according to the embodiment 2, the ESD countermeasure using the inductor of the present disclosure becomes effective for the amplifier circuit 3 that has a high likelihood of failure because of a great number of ground points.

### Other Embodiments

The amplifier circuits according to the present disclosure have been described above using the embodiments. However, the present disclosure is not limited to the foregoing embodiments. Other embodiments realized by combining optional constituent elements of the foregoing embodiments, modified examples obtained by applying various modifications apparent to those skilled in the art to the foregoing embodiments without necessarily departing the scope of the present disclosure, and various devices including the amplifier circuit according to the present disclosure may also be included in the present disclosure.

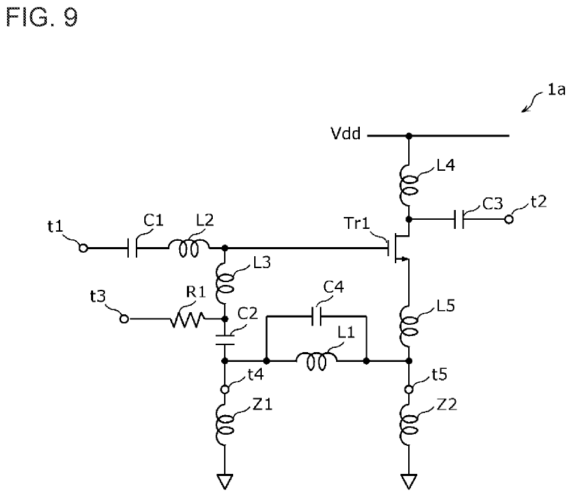

For example, in the foregoing embodiments, the examples are described using the case where the coiled or meandered inductor is connected between the ground terminals. Alternatively, by connecting a capacitor in parallel to that inductor, a LC parallel circuit may be connected between the ground terminals. Such a case will be described using FIG. 9.

FIG. 9 is a circuit configuration diagram illustrating an example of an amplifier circuit 1a according to another embodiment.

The amplifier circuit 1a according to another embodiment includes a capacitor C4 that is connected in parallel to the inductor L1. For example, the inductor L1 and the capacitor C4 that constitute a LC parallel circuit may be formed in a wiring layer that is provided on a semiconductor substrate. The remaining points are the same as those of the embodiment 1, and thus the descriptions thereof are omitted.

As is the case with the amplifier circuit 1 according to the embodiment 1, because the coiled or meandered inductor L1 is connected between the ground terminals t4 and t5 to which the two terminals of the transistor Tr1 are connected, it becomes possible to realize the amplifier circuit 1a that facilitates both the ESD protection and the oscillation suppression.

Further, in the amplifier circuit 1a, the LC parallel circuit is connected between the ground terminals t4 and t5. Thus, it becomes possible to further suppress the passage of a signal of a particular frequency between the ground terminals t4 and t5. For example, by adjusting the inductance value of the inductor L1 and the capacitance value of the capacitor C4, it becomes possible to prevent a signal of a frequency at which the signal is intended to be amplified by the amplifier circuit 1a from passing between the ground terminals t4 and t5. Even in the case where the inductance value of the inductor L1 is small, by adjusting the capacitance value of the capacitor C4, it becomes possible to prevent a signal of the frequency at which the signal is intended to be amplified by the amplifier circuit 1a from passing between the ground terminals t4 and t5.

Note that also in the amplifier circuit 2 according to the embodiment 2 and the amplifier circuit 3 according to the embodiment 3, a LC parallel circuit may be connected between the ground terminals by connecting a capacitor in parallel to the coiled or meandered inductor connected between the ground terminals.

Note that in the foregoing embodiments, the examples are described using the case where two terminals of the gate, the source, and the drain of the transistor are connected to the ground terminals that are different from each other. Regarding this, a terminal other than these two terminals may be connected to the ground terminal to which one of these two terminals are connected. For example, in the case where these two terminals are the gate and the drain, the source may be connected to the ground terminal to which the gate is connected. That is to say, the gate and the source may be connected to a common ground terminal, and the drain may be connected to the ground terminal that is different from this common ground terminal.

### INDUSTRIAL APPLICABILITY

The present disclosure can be widely used in communication devices such as mobile phones and the like as an amplifier circuit that amplifies a radio frequency signal.

### REFERENCE SIGNS LIST

1, 1a, 2, 3 Amplifier circuit
11 Semiconductor substrate
12 Semiconductor layer
13 Wiring layer
14 Insulator
15 Body
16 Copper pillar
17 Solder bump
18 Mold resin
19 Buried oxide layer
21 Surface layer electrode
22 Via
23 Internal layer electrode
24 Dielectric layer
25 Ground plane electrode
C1, C2, C3, C4, C11, C12, C13, C14, C15, C16, C21, C22, C23, C24 Capacitor
L1, L2, L3, L4, L5, L11, L12, L13, L14, L15, L16, L21, L22, L23, L24, L25, L26 Inductor
R1, R11, R21 Resistor
t1, t11, t21 Input terminal
t2, t12, t22 Output terminal
t3, t13, t14, t23 Bias terminal
t4, t5, t15, t16, t17, t24, t25, t26 Ground terminal
Tr1, Tr11, Tr12, Tr21, Tr22 Transistor
Vdd Power
Z, Z1, Z2, Z11, Z12, Z13, Z21, Z22, Z23 Ground impedance component

1. An amplifier circuit comprising:
an input terminal;
an output terminal;
a first transistor connected between the input terminal and the output terminal; and
a coiled or meandered inductor,
wherein the first transistor has a first control terminal, a first terminal, and a second terminal,
wherein two of the first control terminal, the first terminal, and the second terminal are connected to two different ground terminals, and
wherein the inductor is connected between the two different ground terminals.

2. An amplifier circuit comprising:
an input terminal;
an output terminal;
a first transistor connected between the input terminal and the output terminal;
a second transistor connected between the input terminal and the output terminal, the second transistor being connected to the first transistor in a multistage manner; and
a coiled or meandered inductor,
wherein the first transistor has a first control terminal, a first terminal, and a second terminal,
wherein the second transistor has a second control terminal, a third terminal, and a fourth terminal,
wherein two of the first control terminal, the second control terminal, the first terminal, the second terminal, the third terminal, and the fourth terminal are connected to two different ground terminals, and
wherein the inductor is connected between the two different ground terminals.

3. The amplifier circuit according to claim 2, wherein one of the first control terminal, the first terminal, and the second terminal, and one of the second control terminal, the third terminal, and the fourth terminal, are connected to the two different ground terminals.

4. The amplifier circuit according to claim 1, further comprising:
a capacitor connected in parallel to the inductor.

5. The amplifier circuit according to claim 2, further comprising:
a capacitor connected in parallel to the inductor.

6. The amplifier circuit according to claim 1, wherein the inductor is in a wiring layer on a semiconductor substrate.

7. The amplifier circuit according to claim 2, wherein the inductor is in a wiring layer on a semiconductor substrate.

8. The amplifier circuit according to claim 4, wherein
the inductor and the capacitor are in a wiring layer on a semiconductor substrate.

9. The amplifier circuit according to claim 5, wherein
the inductor and the capacitor are in a wiring layer on a semiconductor substrate.
